(19) United States
(12) Patent Application Publication
(10) Pub. No.: US 2025/0112053 A1
(43) Pub. Date: Apr. 3, 2025

(54) MANUFACTURING METHOD OF CMOS ACOUSTIC PRESSURE SENSOR

(71) Applicant: CHUAN-WEI WANG, Taiwan (CN)

(72) Inventor: CHUAN-WEI WANG, Taiwan (CN)

(21) Appl. No.: 18/891,980

(22) Filed: Sep. 20, 2024

(30) Foreign Application Priority Data
Sep. 28, 2023 (TW) 112137566

(51) Int. Cl. H01L 21/3065; G01L 11/04; H01L 21/311

(52) U.S. Cl. CPC H01L 21/3065; G01L 11/04; H01L 21/31116

(57) ABSTRACT

This invention discloses a method for manufacturing a CMOS acoustic pressure sensor. After completing the CMOS process, a cavity is etched into the substrate of the CMOS wafer, and then the oxide insulation structure on the front side of the CMOS wafer is removed, thereby completing the fabrication of the CMOS acoustic pressure sensor.

### CROSS-REFERENCE TO RELATED APPLICATIONS

The application claims priority to Taiwan patent application No. 112137566, filed on Sep. 28, 2023, the entire contents of which are incorporated herein by reference.

### TECHNICAL FIELD

The present invention relates to a method for making an acoustic pressure sensor, and in particular to a method for making a CMOS (complementary metal oxide semiconductor) acoustic pressure sensor.

### BACKGROUND

CMOS (Complementary Metal-Oxide-Semiconductor) technology has been widely used in the manufacturing of integrated circuits (ICs), particularly in advanced smartphone chips and image sensor chips (CIS). Due to significant research and investment, the development and innovation of ICs have achieved rapid progress, greatly enhancing their reliability and yield, while also significantly reducing production costs. Currently, this technology has reached a mature and stable level. For the continuous development of semiconductors, in addition to following current technological trends, breakthroughs must be achieved by providing specialized production processes to enhance system integration.

In this regard, Micro-Electro-Mechanical Systems (MEMS) is a new processing technology completely different from traditional methods. It mainly utilizes semiconductor technology to produce MEMS structures, while also being capable of manufacturing structures with both electronic and mechanical functions. Therefore, it has the advantages of mass processing, miniaturization, and high performance, making it highly suitable for technologies requiring large-scale production at reduced costs. Consequently, integrating CMOS circuits with MEMS can be the best method to achieve system integration. In traditional technology, as shown in FIG. 1, a MEMS capacitive acoustic pressure sensor 1 typically includes a fixed electrode 6, an insulating layer 10, a conductive film 12, and a semiconductor substrate 14. There is a gap between the fixed electrode 7 and the conductive film 12, and a cavity 16 is formed in the semiconductor substrate 14 below the conductive film 12. When sound pressure is transmitted through the air to the conductive film 12, the conductive film 12 vibrates. As the conductive film 12 vibrates up and down, a capacitance change occurs between the conductive film 12 and the fixed electrode 7, which is then converted into a voltage signal to detect changes in sound pressure. U.S. Pat. No. 8,692,340 describes a technique where CMOS and MEMS processes are respectively performed on two different semiconductor substrates, and then the two semiconductor substrates are bonded together to form an acoustic pressure sensor. However, this technology has higher manufacturing costs and cannot be arrayed.

Therefore, the present invention addresses the above-mentioned issues and proposes a method for manufacturing a CMOS acoustic pressure sensor to resolve the problems associated with conventional methods.

### SUMMARY

The primary objective of the present invention is to provide a method for manufacturing a CMOS acoustic pressure sensor, which mainly aims to enhance the performance of the sensor and reduce production and testing costs.

To achieve the above objective, the present invention provides a method for manufacturing a CMOS acoustic pressure sensor. First, a CMOS process is provided, which includes, in sequence, a semiconductor substrate, a first oxide insulation layer, a doped polysilicon layer, a second oxide insulation layer, and a metal wiring layer. The CMOS process typically involves multiple layers of metal wiring, with oxide insulation layers or via between each metal wiring layer. Therefore, the CMOS process usually includes at least one doped polysilicon layer and one metal wiring layer. In the manufacturing of the sensor, reactive ion etching (RIE) can be used to remove the oxide insulation layer in the CMOS process, and inductively coupled plasma (ICP) etching can be used to etch the substrate to complete the cavity, thereby forming a CMOS acoustic pressure sensor.

In one embodiment of the present invention, the metal wiring layer further includes multiple patterned metal layers and multiple via, which serve as the sensing electrode. The film is composed of polysilicon, and the sensing electrode is connected to the film, with the other end of the sensing electrode fixed.

In another embodiment of the present invention, the metal wiring layer further includes multiple patterned metal layers and multiple via, which serve as the sensing electrode. The film is composed of an oxide insulation layer and polysilicon, with the sensing electrode connected to the film and fixed at the other end.

In another embodiment of the present invention, the metal wiring layer further includes multiple patterned metal layers and multiple via, which serve as the sensing electrode. The film is composed of an oxide insulation layer and a metal wiring layer, with the sensing electrode connected to the film and fixed at the other end.

The metal wiring layer further includes multiple patterned metal layers and multiple metal via, which serve as the sensing electrode. The film is composed of an oxide insulation layer, polysilicon, and a metal wiring layer, with the sensing electrode connected to the film and fixed at the other end.

In one embodiment of the present invention, the CMOS acoustic pressure sensor can be an array-type acoustic pressure sensor, with several CMOS acoustic pressure sensors of the same size on a single chip.

In another embodiment of the present invention, the CMOS acoustic pressure sensor can be an array-type acoustic pressure sensor, with several CMOS acoustic pressure sensors of different sizes on a single chip.

In one embodiment of the present invention, the polysilicon layer further includes undoped polysilicon, which is non-conductive in this context.

Based on the above, the method for manufacturing a CMOS acoustic pressure sensor can effectively enhance sensor performance and reduce testing and packaging costs.

Below, the embodiments are described in detail in cooperation with the drawings to make easily understood the technical contents, characteristics and accomplishments of the present invention.

### BRIEF DESCRIPTION OF DRAWINGS

FIG. 1 is a cross-sectional view of the structure of a prior art MEMS capacitive acoustic pressure sensor.

FIGS. 2A to 2C are cross-sectional views of each step in the first embodiment of the method for manufacturing a CMOS acoustic pressure sensor according to the present invention.

FIG. 3 is a top view of the sensing structure in the second embodiment of the present invention.

FIG. 4 is a cross-sectional view along the A-A′ line of FIG. 3.

FIG. 5 is a top view of the same-size array-type CMOS acoustic pressure sensor in the third embodiment of the present invention.

FIG. 6 is a top view of the different-size array-type CMOS acoustic pressure sensor in the fourth embodiment of the present invention.

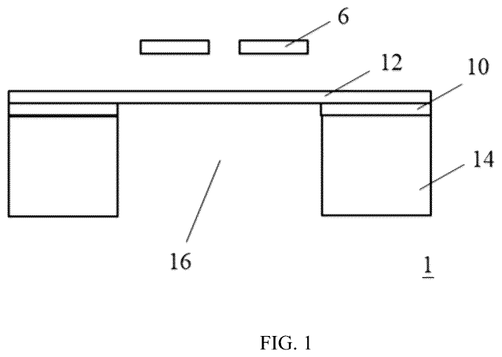

### DETAILED DESCRIPTION OF THE EMBODIMENTS

The embodiments of the present invention will be further explained in the following sections in conjunction with the relevant figures. To the extent possible, the same reference numbers in the figures and the specification represent the same or similar components. In the figures, shapes and thicknesses may be exaggerated for simplicity and ease of identification. It should be understood that components not specifically shown in the figures or described in the specification are known to those skilled in the art. Those skilled in the art can make various changes and modifications based on the content of the present invention.

When a component is referred to as being “on . . . ” it may mean that the component is directly on another component or that other components may be present in between. Conversely, when a component is referred to as “directly on” another component, it means no other components are present between them. As used herein, the term “and/or” includes any and all combinations of one or more of the associated items.

In the following description, the term “an embodiment” or “one embodiment” refers to a particular element, structure, or feature related to at least one embodiment. Therefore, multiple occurrences of “an embodiment” or “one embodiment” in the following description do not necessarily refer to the same embodiment. Moreover, specific elements, structures, and features in one or more embodiments may be combined as appropriate.

The disclosure is specifically described in the following examples, which are merely illustrative, as various modifications and refinements may be made without departing from the spirit and scope of the present disclosure, as understood by those skilled in the art. Therefore, the scope of the present disclosure should be determined by the claims that follow. In the specification and claims, unless clearly specified otherwise, the meaning of “a” and “the” includes “one or at least one” of the elements or components. Additionally, as used herein, unless clearly specified otherwise in the specific context, the singular article also includes the plural description of elements or components. Furthermore, as applied in the specification and in the following claims, unless the context clearly specifies otherwise, the meaning of “therein” can include “therein” and “thereon.” The terms used in the specification and claims, unless specifically defined, generally have their ordinary meaning as understood in the relevant field. Certain terms used to describe the present disclosure will be discussed below or elsewhere in the specification to provide additional guidance for practitioners in understanding the present disclosure. In any instance where examples are given in the specification, including the use of terms therein, these examples are meant to illustrate and are not to limit the scope of the present disclosure or any terms. Similarly, the present disclosure is not limited to the various embodiments presented in the specification.

It should be understood that the terms “comprising,” “including,” “having,” “containing,” “involving,” and the like, as used herein, are open-ended, meaning “including but not limited to.” Additionally, any embodiment of the present invention or the claims does not need to achieve all objectives, benefits, or characteristics disclosed. Moreover, the summary and titles are only for assistance in patent document searches and are not intended to limit the scope of the invention.

Unless specifically stated otherwise, some conditional terms or words, such as “can,” “could,” “might,” or “may,” generally express that the embodiment has, but may also not require, a certain feature, element, or step. In other embodiments, these features, elements, or steps may not be necessary.

The following introduces a method for manufacturing a CMOS acoustic pressure sensor, using a standard CMOS process to reduce manufacturing costs and improve performance. Generally speaking, in CMOS processes, polysilicon typically contains doped N-type or P-type ions as a conductive material, usually used as gates, resistors, or polysilicon capacitors (PIP, poly interconnect poly). In manufacturing a CMOS acoustic pressure sensor, it acts as an RIE etch stop layer and can define a smaller gap.

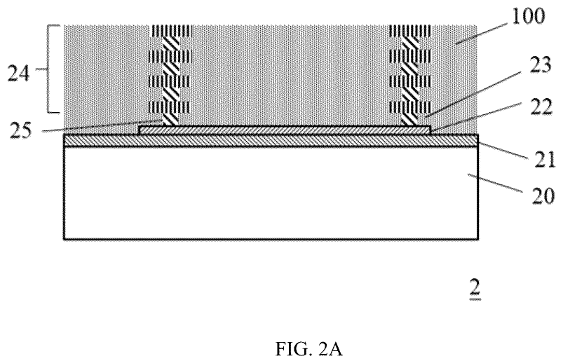

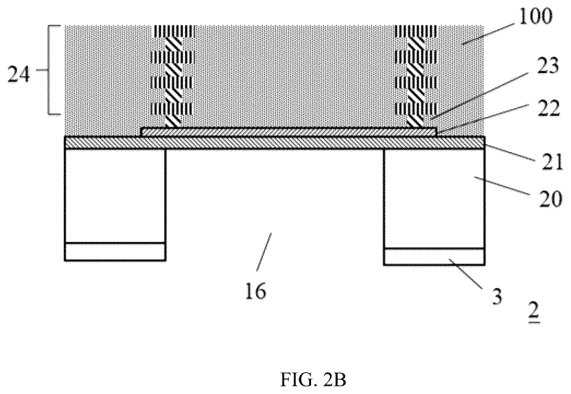

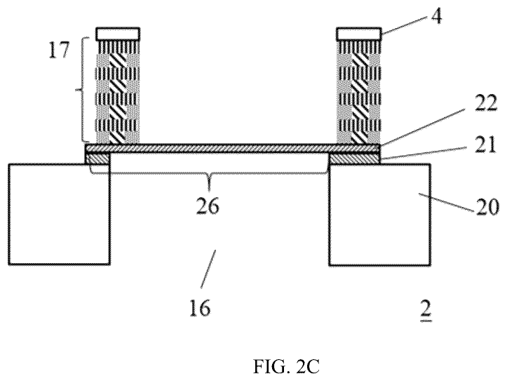

FIGS. 2a to 2c show the cross-sectional views of the steps in the first embodiment of the method for manufacturing a CMOS acoustic pressure sensor according to the present invention. Please refer to FIGS. 2a to 2c for an introduction to the first embodiment of the manufacturing method for a CMOS acoustic pressure sensor according to the present invention. First, as shown in FIG. 2A, a CMOS device 2 is provided, which includes, in sequence, a semiconductor substrate 20, a first oxide insulation layer 21, a doped polysilicon layer 22, a second oxide insulation layer 23, and a metal wiring layer 24. The semiconductor substrate 20 can be, but is not limited to, a silicon substrate. The first oxide insulation layer 21 and the second oxide insulation layer 23 can be silicon dioxide layers, but the invention is not limited to this. The polysilicon layer 22 can be a multi-layer polysilicon layer, meaning an additional polysilicon layer can be added above the second oxide insulation layer 23 in the CMOS device. This is not specifically illustrated in the figures and is known technology. The metal wiring layer 24 is located above the second oxide insulation layer 23, where the metal wiring layer consists of multiple metal wiring layers, oxide insulation layers, and via 25. The via 25 are between the metal wiring layer 24 and the polysilicon layer 22, serving as electrical conduction pathways. The doped polysilicon layer 22 may include undoped polysilicon. Here, the multiple oxide insulation layers and multiple metal wiring layers all serve the same purpose of insulation and signal conduction. Unless for special purposes and other functions, the difference lies only in the illustration for differentiation. For example, the first oxide insulation layer and the second oxide insulation layer function as insulation. All of the above are standard CMOS process-known technologies.

Next, as shown in FIG. 2b, an inductively coupled plasma (ICP) is used to remove part of the semiconductor substrate, forming a cavity 16. The cavity is located below the polysilicon layer 22. A mask 3 is placed on the unetched area of the semiconductor substrate 14. The mask 3 is made of photoresist or thermally formed silicon dioxide. After removing part of the semiconductor substrate, the mask 3 is also removed. Additionally, the cavity can also be formed using chemical etching.

As shown in FIG. 2C, a mask 4 is placed on top of the metal wiring layer, with the mask 4 made of photoresist material. Reactive ion etching (RIE) is used to remove the oxide insulation structure 100, forming a multilayer sensing electrode 17 connected to the film 26. Here, both the polysilicon layer and the metal wiring layer can act as etch stop layers. Subsequently, the mask 4 and the first oxide insulation layer 21 are removed. Further explanation: the film composition can be the polysilicon layer 22 and the oxide insulation layer 21 or the metal wiring layer 24 and the oxide insulation layer below the metal wiring layer 24. The film 26 can also consist of only the polysilicon layer 22. The film's composition will vary according to different material stackings, thereby etching out different film compositions. In known technology, in the CMOS process, the metal wiring layer simultaneously exists with the oxide insulation layer, and the polysilicon layer is similar. The composition of the multilayer sensing electrode 17 includes the metal wiring layer 24, the oxide insulation layer 23, and the via 25.

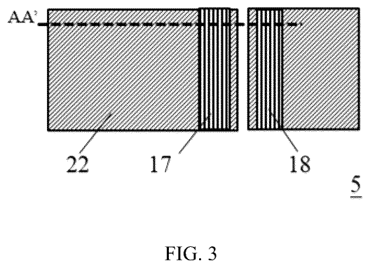

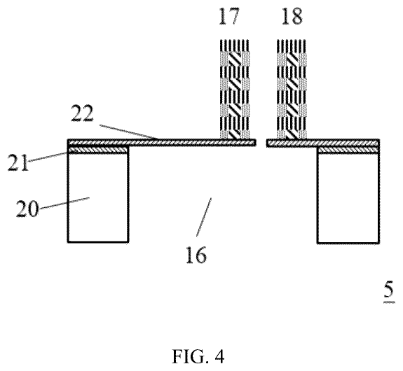

FIG. 3 shows the top view of the sensing structure in the second embodiment of the present invention, and FIG. 4 shows the cross-sectional view along the A-A′ line of FIG. 3. The following introduces the second embodiment of the CMOS acoustic pressure sensor according to the present invention, where the sensing structure 5 includes a film, a multilayer sensing electrode 17, and a multilayer fixed electrode 18. If the polysilicon layer is a conductor, the multilayer sensing electrode and the multilayer fixed electrode below the polysilicon layer 22 are at the same potential or floating potential. In this case, if the polysilicon layer is at floating potential, it implies the same potential. Here, the difference between the multilayer sensing electrode 17 and the multilayer fixed electrode 18 is particularly noted. When the film is displaced due to sound pressure, the multilayer sensing electrode 17 will also be displaced, but the multilayer fixed electrode 18 will not.

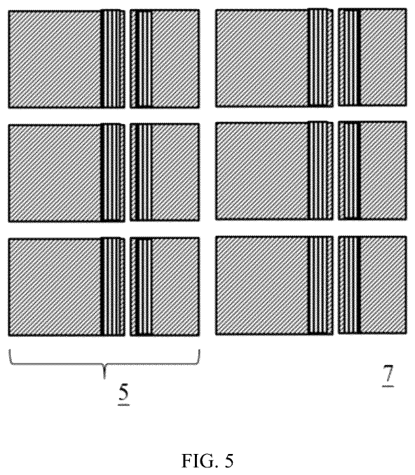

FIG. 5 shows the top view of the same-size array-type CMOS acoustic pressure sensor 7 in the third embodiment of the present invention. The same-size array-type CMOS acoustic pressure sensor is composed of multiple same-size sensing structures 5 and cavities 16. The term “same-size” refers to the identical length, width, and thickness of the film structure, i.e., the same natural resonance frequency. The above-mentioned “same natural resonance frequency” implies no process errors.

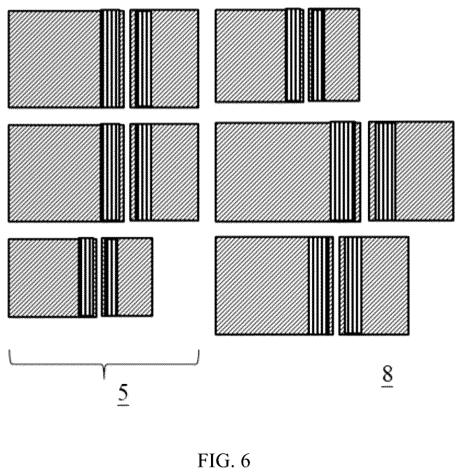

FIG. 6 shows the top view of the different-size array-type CMOS acoustic pressure sensor 8 in the fourth embodiment of the present invention. The different-size array-type CMOS acoustic pressure sensor is composed of multiple different-size sensing structures 5 and cavities 16. The term “different-size” refers to varying lengths, widths, and thicknesses of the film structure, i.e., different natural resonance frequencies. Different sizes of film structures can be designed to enhance specific performance, such as increasing signal gain at low frequencies.

The above description is only a preferred embodiment of the present invention and is not intended to limit the scope of implementation of the present invention. Any equivalent changes and modifications based on the shape, structure, features, and spirit of the present invention described in the patent claims should be included within the scope of the patent claims of the present invention.

What is claimed is:

1. A method for manufacturing a CMOS acoustic pressure sensor, comprising the following steps:
providing a CMOS device;
etching a semiconductor substrate;
using reactive ion etching to remove an oxide insulation structure;
completing the etching to obtain an acoustic pressure sensor;
wherein the acoustic pressure sensor comprises a film, a cavity, a multilayer sensing electrode, and a multilayer fixed electrode, wherein the multilayer sensing electrode is connected to the film.

2. The method for manufacturing a CMOS acoustic pressure sensor according to claim 1, wherein the semiconductor substrate can be etched using inductively coupled plasma or chemical etching.

3. The method for manufacturing a CMOS acoustic pressure sensor according to claim 1, wherein the film includes at least one polysilicon layer, and the polysilicon layer can be non-conductive or at an equivalent potential.

4. A method for manufacturing an array-type CMOS acoustic pressure sensor, comprising the following steps:
providing a CMOS device;
etching a semiconductor substrate;
using reactive ion etching to remove an oxide insulation structure;
completing the etching to obtain multiple acoustic pressure sensors arranged in an array;
wherein the acoustic pressure sensors comprise a film, a cavity, a multilayer sensing electrode, and a multilayer fixed electrode, wherein the multilayer sensing electrode is connected to the film.

5. The method for manufacturing an array-type CMOS acoustic pressure sensor according to claim 4, wherein the acoustic pressure sensors have different sizes.

6. The method for manufacturing an array-type CMOS acoustic pressure sensor according to claim 4, wherein the film includes at least one polysilicon layer, and the polysilicon layer can be non-conductive or at an equivalent potential.

7. The method for manufacturing an array-type CMOS acoustic pressure sensor according to claim 4, wherein the semiconductor substrate can be etched using inductively coupled plasma or chemical etching.

8. A CMOS acoustic pressure sensor, comprising:
a CMOS device; and
an acoustic pressure sensor comprising a film, a cavity, a multilayer sensing electrode, and a multilayer fixed electrode, wherein the multilayer sensing electrode is connected to the film;
wherein the film includes at least one polysilicon layer, and the polysilicon layer can be non-conductive or at an equivalent potential.

9. The CMOS acoustic pressure sensor according to claim 8, wherein the acoustic pressure sensor is manufactured by following steps:
providing a CMOS device;
etching a semiconductor substrate;
using reactive ion etching to remove an oxide insulation structure;
completing the etching to obtain an acoustic pressure sensor;
wherein the acoustic pressure sensor comprises a film, a cavity, a multilayer sensing electrode, and a multilayer fixed electrode, wherein the multilayer sensing electrode is connected to the film.

10. The CMOS acoustic pressure sensor according to claim 9, wherein the semiconductor substrate can be etched using inductively coupled plasma or chemical etching.

11. The CMOS acoustic pressure sensor according to claim 9, wherein the film includes at least one polysilicon layer, and the polysilicon layer can be non-conductive or at an equivalent potential.

12. The CMOS acoustic pressure sensor according to claim 8, wherein the acoustic pressure sensor is an array of multiple acoustic pressure sensors manufactured by following steps:
providing a CMOS device;
etching a semiconductor substrate;
using reactive ion etching to remove an oxide insulation structure; and
completing the etching to obtain multiple acoustic pressure sensors arranged in an array;
wherein the acoustic pressure sensors comprise a film, a cavity, a multilayer sensing electrode, and a multilayer fixed electrode, wherein the multilayer sensing electrode is connected to the film.
